(19) United States
(12) Patent Application Publication
(10) Pub. No.: US 2024/0332308 A1
(43) Pub. Date: Oct. 3, 2024

(54) SEMICONDUCTOR DEVICE AND MANUFACTURING METHOD THEREOF

(71) Applicant: Japan Display Inc., Tokyo (JP)

(72) Inventors: Marina MOCHIZUKI, Tokyo (JP); Masahiro WATABE, Tokyo (JP); Masashi TSUBUKU, Tokyo (JP); Hajime WATAKABE, Tokyo (JP); Toshinari SASAKI, Tokyo (JP); Takaya TAMARU, Tokyo (JP); Ryo ONODERA, Tokyo (JP)

(73) Assignee: Japan Display Inc., Tokyo (JP)

(21) Appl. No.: 18/597,186

(22) Filed: Mar. 6, 2024

(30) Foreign Application Priority Data
Mar. 31, 2023 (JP) 2023-058279

(51) Int. Cl. H01L 27/12; G02F 1/1368; H01L 29/786; H10K 59/121

(52) U.S. Cl. CPC H01L 27/1225; G02F 1/1368; H01L 27/1274; H01L 29/7869; H10K 59/1213

(57) ABSTRACT

A semiconductor device includes a gate electrode, a gate insulating layer over the gate electrode, an oxide semiconductor layer having a polycrystalline structure over the gate insulating layer, a source electrode and a drain electrode over the oxide semiconductor layer, and an interlayer insulating layer in contact with the oxide semiconductor layer. The interlayer insulating layer covers the source electrode and the drain electrode. The oxide semiconductor layer includes a first region overlapping one of the source electrode and the drain electrode and a second region in contact with the interlayer insulating layer. A difference between a film thickness of the first region and a film thickness of the second region is less than or equal to 5 nm.

### CROSS-REFERENCE TO RELATED APPLICATIONS

This application claims the benefit of priority to Japanese Patent Application No. 2023-058279, filed on Mar. 31, 2023, the entire contents of which are incorporated herein by reference.

### FIELD

An embodiment of the present invention relates to a semiconductor device. Specifically, an embodiment of the present invention relates to a semiconductor device using an oxide semiconductor as a channel. In addition, an embodiment of the present invention relates to a method for manufacturing a semiconductor device.

### BACKGROUND

In recent years, instead of a silicon semiconductor film using amorphous silicon, low-temperature polysilicon, and single-crystal silicon, a semiconductor device in which an oxide semiconductor film is used for a channel has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including an oxide semiconductor film can be fabricated with a simple structure and low-temperature process, similar to a semiconductor device including an amorphous silicon film. The semiconductor device including an oxide semiconductor film is known to have higher mobility than the semiconductor device including an amorphous silicon film.

### SUMMARY

A semiconductor device according to an embodiment of the present invention includes a gate electrode, a gate insulating layer over the gate electrode, an oxide semiconductor layer having a polycrystalline structure over the gate insulating layer, a source electrode and a drain electrode over the oxide semiconductor layer, and an interlayer insulating layer in contact with the oxide semiconductor layer. The interlayer insulating layer covers the source electrode and the drain electrode. The oxide semiconductor layer includes a first region overlapping one of the source electrode and the drain electrode and a second region in contact with the interlayer insulating layer. A difference between a film thickness of the first region and a film thickness of the second region is less than or equal to 5 nm.

A method for manufacturing a semiconductor device according to an embodiment of the present invention includes the steps of forming a gate electrode, forming a gate insulating layer over the gate electrode, forming an oxide semiconductor layer having a polycrystalline structure over the gate insulating layer, depositing a conductive film over the oxide semiconductor layer, patterning the conductive film by etching to form a source electrode and a drain electrode, and forming an interlayer insulating layer in contact with the oxide semiconductor layer. The interlayer insulating layer covers the source electrode and the drain electrode. The oxide semiconductor layer includes a first region overlapping one of the source electrode and the drain electrode and a second region in contact with the interlayer insulating layer. A difference between a film thickness of the first region and a film thickness of the second region is less than or equal to 5 nm.

### BRIEF DESCRIPTION OF DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is a flowchart showing a method for manufacturing a semiconductor device according to an embodiment of the present invention.

FIG. 4 is a schematic cross-sectional view showing a method for manufacturing a semiconductor device according to an embodiment of the present invention.

FIG. 5 is a schematic cross-sectional view showing a method for manufacturing a semiconductor device according to an embodiment of the present invention.

FIG. 6 is a schematic cross-sectional view showing a method for manufacturing a semiconductor device according to an embodiment of the present invention.

FIG. 7 is a schematic cross-sectional view showing a method for manufacturing a semiconductor device according to an embodiment of the present invention.

FIG. 8 is a schematic cross-sectional view showing a method for manufacturing a semiconductor device according to an embodiment of the present invention.

FIG. 9 is a schematic cross-sectional view showing a method for manufacturing a semiconductor device according to an embodiment of the present invention.

FIG. 10 is a schematic cross-sectional view showing a method for manufacturing a semiconductor device according to an embodiment of the present invention.

FIG. 11 is a schematic cross-sectional view showing a method for manufacturing a semiconductor device according to an embodiment of the present invention.

FIG. 12 is a plan view showing an outline of a display device according to an embodiment of the present invention.

FIG. 13 is a block diagram showing a circuit configuration of a display device according to an embodiment of the present invention.

FIG. 14 is a circuit diagram showing a pixel circuit of a display device according to an embodiment of the present invention.

FIG. 15 is a schematic cross-sectional view showing a configuration of a display device according to an embodiment of the present invention.

FIG. 16 is a circuit diagram showing a pixel circuit of a display device according to an embodiment of the present invention.

FIG. 17 is a schematic plan view showing a configuration of a display device according to an embodiment of the present invention.

FIG. 18 is a diagram showing electrical characteristics (Id-Vg characteristics) of Samples A to C in Example 2.

### DESCRIPTION OF EMBODIMENTS

In a conventional semiconductor device including an oxide semiconductor film, however, since the etching resistance of the oxide semiconductor film is low, it is difficult to control the shape of the oxide semiconductor film. In particular, in semiconductor devices manufactured using a large-area substrate, variations in the shape of oxide semiconductor films cause variations in the electrical characteristics of the semiconductor devices, which is a factor in reducing yield.

An embodiment of the present invention can provide a semiconductor device with little variation and stable electrical characteristics. Further, an embodiment of the present invention can provide a method for manufacturing a semiconductor device in which manufacturing variations are reduced and yield is improved.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of the respective portions in comparison with the actual embodiments. However, the illustrated shapes are merely examples, and do not limit the interpretation of the present invention. In the present specification and the drawings, the same reference sings are given to elements similar to those described previously with respect to the above-described drawings, and detailed description thereof may be omitted as appropriate.

In the present specification, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, unless there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

A direction from a substrate toward an oxide semiconductor layer is referred to as upper or above in each embodiment of the present invention. Conversely, a direction from the oxide semiconductor layer to the substrate is referred to as lower or below. For convenience of explanation, the phrase “above” or “below” is used for description, but for example, the substrate and the oxide semiconductor layer may be arranged so that the vertical relationship is reversed from that shown in the drawings. In the following explanation, for example, the expression “an oxide semiconductor layer on a substrate” merely describes the vertical relationship between the substrate and the oxide semiconductor layer as described above, and another member may be arranged between the substrate and the oxide semiconductor layer. The terms “above” or “below” mean a stacking order in which a plurality of layers is stacked, and may have a positional relationship in which a transistor and a pixel electrode do not overlap in a plan view when expressed as a pixel electrode above a transistor. On the other hand, the case of the expression a pixel electrode vertically above a transistor means a positional relationship in which the transistor and the pixel electrode overlap in a plan view. In addition, a plan view refers to viewing from a direction perpendicular to a surface of the substrate.

In the specification, the terms “film” and “layer” can optionally be interchanged with one another.

In the specification, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other elements.

In addition, the following embodiments can be combined as long as there is no technical contradiction.

### First Embodiment

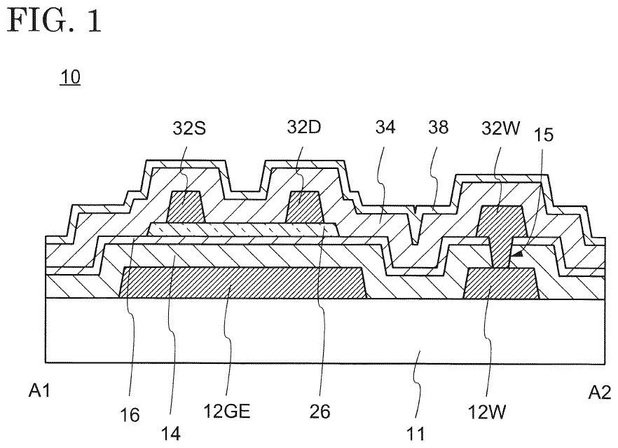

A semiconductor device 10 according to an embodiment of the present invention is described with reference to FIGS. 1 to 11.

### [Configuration of Semiconductor Device 10]

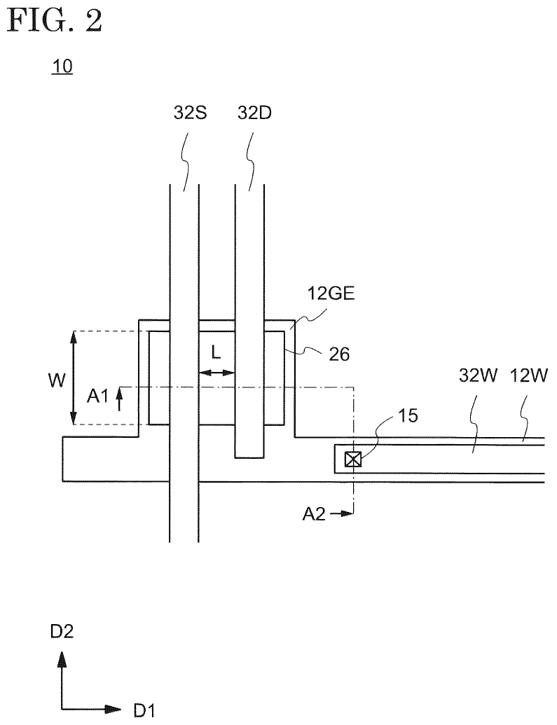

A configuration of the semiconductor device 10 according to an embodiment of the present invention is described with reference to FIGS. 1 and 2. FIG. 1 is a schematic cross-sectional view showing a configuration of the semiconductor device 10 according to an embodiment of the present invention. FIG. 2 is a schematic plan view showing a configuration of the semiconductor device 10 according to an embodiment of the present invention. The cross-sectional view shown in FIG. 1 corresponds to a cross section cut along a line A1-A2 shown in FIG. 2.

The semiconductor device 10 is arranged over a substrate 11 as shown in FIG. 1. The semiconductor device 10 includes a gate electrode 12GE, gate insulating layers 14 and 16, an oxide semiconductor layer 26, a source electrode 32S, a drain electrode 32D, and interlayer insulating layers 34 and 38. In the case where the source electrode 32S and the drain electrode 32D are not particularly distinguished from each other, they may be referred to as a source electrode and drain electrode 32. Further, the gate electrode 12GE, the gate insulating layers 14 and 16, and the oxide semiconductor layer 26 may be referred to as a transistor. The semiconductor device 10 is a so-called bottom-gate transistor in which the gate electrode 12GE is provided below the oxide semiconductor layer 26.

Although a bottom-gate transistor is exemplified as the semiconductor device 10 in the present embodiment, the semiconductor device 10 is not limited to the bottom-gate transistor. For example, the semiconductor device 10 may be a dual-gate transistor in which the gate electrode is provided over and below the oxide semiconductor layer 26.

The gate electrode 12GE is provided over the substrate 11. The gate insulating layers 14 and 16 are provided over the substrate 11 and the gate electrode 12GE. The gate insulating layers 14 and 16 have a stacked structure and the gate insulating layer 16 is provided over the gate insulating layer 14. The oxide semiconductor layer 26 is provided over the gate insulating layers 14 and 16. The source electrode 32S and the drain electrode 32D are provided over the oxide semiconductor layer 26. The interlayer insulating layers 34 and 38 are provided over the oxide semiconductor layer 26, the source electrode 32S, and the drain electrode 32D. The interlayer insulating layers 34 and 38 have a stacked structure and the interlayer insulating layer 38 is provided over the interlayer insulating layer 34. That is, the interlayer insulating layers 34 and 38 cover the source electrode 32S and the drain electrode 32D, and the interlayer insulating layer 34 is in contact with the oxide semiconductor layer 26.

The oxide semiconductor layer 26 overlaps the gate electrode 12GE in a plan view as shown in FIG. 2. A direction D1 is a direction connecting the source electrode 32S and the drain electrode 32D, and a direction D2 is a direction perpendicular to the direction D1. A channel length L corresponds to a length of a region (channel region) of the oxide semiconductor layer 26 between the source electrode 32S and the drain electrode 32D in the direction D1, and a channel width W corresponds to a width of the channel region in the direction D2, in the semiconductor device 10. A region of the oxide semiconductor layer 26 overlapping the source electrode 32S is a source region, and a region of the oxide semiconductor layer 26 overlapping the drain electrode 32D is a drain region, in a plan view. That is, the channel region is located between the source region and the drain region.

A wiring 12W and a wiring 32W function as a gate wiring. The wiring 32W is electrically connected to the wiring 12W via a contact hole 15. Although details are described later, the wiring 12W is formed as the same layer as the gate electrode 12GE. In addition, the wiring 32W is formed as the same layer as the source electrode 32S and the drain electrode 32D. Further, the wiring 32W may not be provided over the wiring 12W.

The oxide semiconductor layer 26 has light transmittance and has a polycrystalline structure containing a plurality of grains. Although details are described later, the oxide semiconductor layer 26 having the polycrystalline structure can be formed by using a Poly-OS (Poly-crystalline Oxide Semiconductor) technique. Therefore, the oxide semiconductor included in the oxide semiconductor layer 26 may be described as Poly-OS hereinafter.

Poly-OS contains two or more metal elements including indium, and the ratio of indium to the two or more metal elements is greater than or equal to 50%. Gallium (Ga), zinc (Zn), aluminum (Al), hafnium (Hf), yttrium (Y), zirconium (Zr), or a lanthanide-based element is used as the metal element other than indium. Elements other than those mentioned above may be used as the oxide semiconductor layer 26.

A particle diameter of the crystal grain contained in Poly-OS is greater than or equal to 0.1 μm, preferably greater than or equal to 0.3 μm, and more preferably greater than or equal to 0.5 μm. For example, the particle diameter of the crystal grain can be obtained using a SEM observation, a TEM observation, or an electron back scattered diffraction (EBSD) method of the oxide semiconductor layer 26.

Since the particle diameter of the crystal grain included in Poly-OS is greater than or equal to 0.1 μm as described above, there is a region containing only one crystal grain along a thickness direction, in the oxide semiconductor layer 26 having a thickness greater than or equal to 10 nm and less than or equal to 30 nm.

Poly-OS has excellent etching resistance. Although details are described later, Poly-OS has excellent etching resistance against an etching solution or an etching gas used in forming the source electrode 32S and the drain electrode 32D. Therefore, the oxide semiconductor layer 26 is hardly etched when forming the source electrode 32S and the drain electrode 32D. Therefore, a thickness of the first region of the oxide semiconductor layer 26 overlapping one of the source electrode 32S and the drain electrode 32D (that is, the source region or the drain region) is substantially the same as a thickness of the second region of the oxide semiconductor layer 26 not overlapping the source electrode 32S and the drain electrode 32D (that is, the channel region). In other words, the difference between the thickness of the first region and the thickness of the second region is less than or equal to 5 nm, preferably less than or equal to 3 nm, and more preferably less than or equal to 1 nm.

The thickness of the channel region affects the electrical characteristics of the semiconductor device. If the variation in the thickness of the channel region is large, it is not possible to provide a semiconductor device having stable electrical characteristics. That is, the yield of the semiconductor device decreases. On the other hand, the semiconductor device 10 has stable electrical characteristics because it is possible to control the thickness of the channel region of the oxide semiconductor layer 26. For example, even when the gate insulating layers 14 and 16 have a large thickness greater than or equal to 300 nm in the semiconductor device 10, it is possible to obtain a field-effect mobility (field-effect mobility in a linear region) that is greater than or equal to 15 cm²/Vs and further greater than or equal to 20 cm²/Vs in a range where the channel length L of the channel region is greater than or equal to 2 μm and less than or equal to 4 μm and the channel width of the channel region is greater than or equal to 2 μm and less than or equal to 25 μm. Therefore, the semiconductor device 10 has improved voltage resistance and stable electrical characteristics even under high voltage.

### [Manufacturing Method of Semiconductor Device 10]

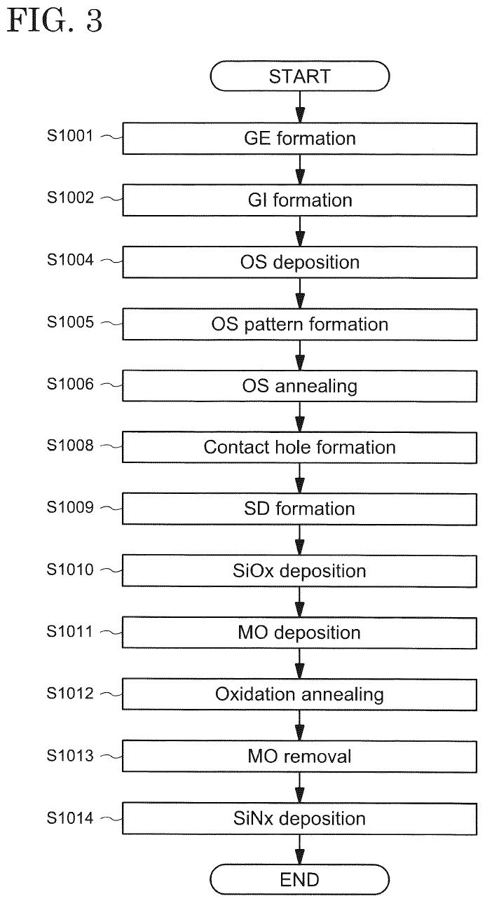

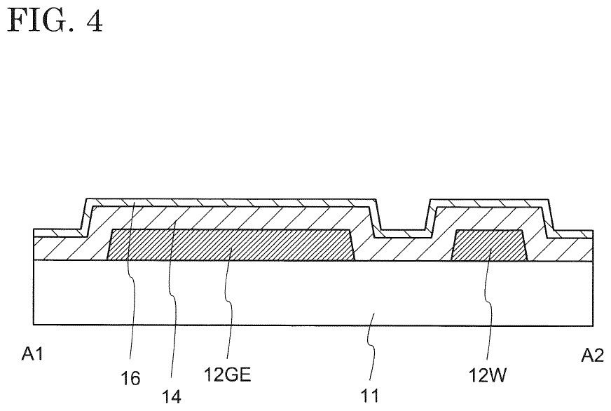

A method for manufacturing the semiconductor device 10 according to an embodiment of the present invention is described with reference to FIGS. 3 to 11. FIG. 3 is a flowchart illustrating a method for manufacturing the semiconductor device 10 according to an embodiment of the present invention. FIGS. 4 to 11 are schematic cross-sectional views showing a method for manufacturing the semiconductor device 10 according to an embodiment of the present invention. Hereinafter, each step of the flowchart shown in FIG. 3 is described in order.

In step S1001 (“GE formation”) of FIG. 3, the gate electrode 12GE is formed on the substrate 11 (see FIG. 4).

A rigid substrate having light transmittance, such as a glass substrate, a quartz substrate, a sapphire substrate, or the like, is used as the substrate 11. If the substrate 11 needs to have flexibility, a polyimide substrate, an acryl substrate, a siloxane substrate, a fluororesin substrate, or the like, or a substrate containing resin, is used as the substrate 11. In the case where the substrate containing resin is used as the substrate 11, an impurity element may be introduced into the resin to improve the heat resistance of the substrate 11. Further, in the case where the display device 10 is used for an integrated circuit, a substrate without translucency such as a semiconductor substrate such as a silicon substrate, a silicon carbide substrate, or a conductive substrate such as a stainless substrate may be used as the substrate 11.

The gate electrode 12GE is formed by processing a conductive film formed by a sputtering method. For example, a metal material is used for the gate electrode 12GE. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys thereof or compounds thereof are used for the gate electrode 12GE. The above-described metal materials may be used in a single layer or in a stacked layer as the gate electrode 12GE.

In step S1002 (“GI formation”) of FIG. 3, the gate insulating layers 14 and 16 are formed over the gate electrode 12GE (see FIG. 4). The gate insulating layers 14 and 16 are formed by a CVD (Chemical Vapor Deposition) method or a sputtering method. An insulating material is used as the gate insulating layers 14 and 16. For example, an inorganic insulating material such as silicon oxide (SiOₓ), silicon oxynitride (SiOₓN_{y}), silicon nitride (SiNₓ), and silicon nitride oxide (SiNₓO_{y}) are used as the insulating material of the gate insulating layers 14 and 16. The above SiOₓN_{y} is a silicon compound containing a smaller proportion (x>y) of nitrogen (N) than oxygen (O). SiNₓO_{y} is a silicon compound containing a smaller proportion of oxygen than nitrogen (x>y).

The gate insulating layer 14 in which an insulating material containing nitrogen is used and the gate insulating layer 16 in which an insulating material containing oxygen is used are preferably formed in this order above the substrate 11. When the insulating material containing nitrogen is used for the gate insulating layer 14, it can block impurities diffusing from the substrate 11 toward the oxide semiconductor layer 26. Further, when the insulating material containing oxygen is used for the gate insulating layer 16, it can release oxygen by heat treatment. For example, a temperature of the heat treatment at which the insulating material containing oxygen releases oxygen is lower than or equal to 500° C., lower than or equal to 450° C., or lower than or equal to 400° C. In addition, the insulating material containing oxygen may release oxygen when heated in any of the steps of the manufacturing process of the semiconductor device 10.

A thickness of the gate insulating layer 14 is preferably greater than a thickness of the gate insulating layer 16. For example, 300 nm of the silicon nitride is formed for the gate insulating layer 14 in the present embodiment. For example, 100 nm of the silicon oxide is formed for the gate insulating layer 16.

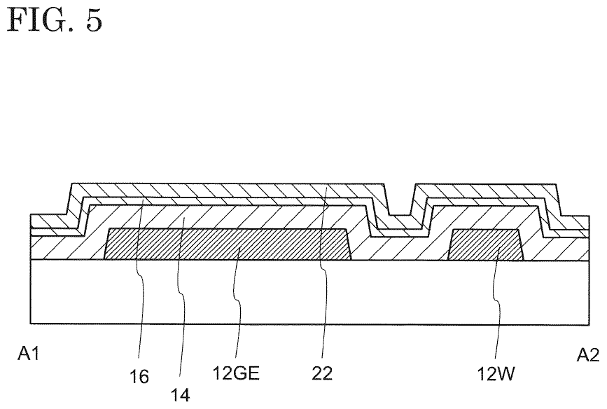

In step S1004 (“OS deposition”) of FIG. 3, an oxide semiconductor film 22 is formed on the gate insulating layer 14 and 16 (see FIG. 5). The oxide semiconductor film 22 is formed by a sputtering method or an atomic layer deposition method (ALD). A thickness of the oxide semiconductor film 22 is greater than or equal to 10 nm and less than or equal to 50 nm, preferably greater than or equal to 10 nm and less than or equal to 40 nm, and more preferably greater than or equal to 10 nm and less than or equal to 30 nm.

A metal oxide having semiconductor properties can be used for the oxide semiconductor film 22. For example, an oxide semiconductor containing two or more metal elements including indium (In) is used for the oxide semiconductor film 22. In addition, the proportion of indium in the two or more metal elements is greater than or equal to 50%. Gallium (Ga), zinc (Zn), aluminum (Al), hafnium (Hf), yttrium (Y), zirconium (Zr), or a lanthanoid-based element is used as the metal element other than indium. The oxide semiconductor film 22 preferably contains a Group 13 element. In addition, an element other than the above may be used as the oxide semiconductor film 22.

In the case where the oxide semiconductor film 22 is crystallized by the OS annealing described later, the oxide semiconductor film 22 after the deposition and before the OS annealing preferably has an amorphous structure (for example, a structure in which the oxide semiconductor has few crystalline components is determined to be amorphous by an XRD method). That is, the oxide semiconductor film 22 is preferably formed under a condition that the oxide semiconductor film 22 immediately after the deposition does not crystallize as much as possible. For example, in the case where the oxide semiconductor film 22 is formed by a sputtering method, the oxide semiconductor film 22 is formed while controlling the temperature of an object to be deposited (the substrate 11 and the structure formed thereon).

Since ions generated in a plasma and atoms recoiled by a sputtering target collide with the object to be deposited when deposition is performed on the object to be deposited by the sputtering method, the temperature of the object to be deposited increases with the deposition treatment. When the temperature of the object to be deposited during the deposition treatment increases, microcrystals are contained in the oxide semiconductor film 22 immediately after the deposition. When the oxide semiconductor film 22 contains microcrystals, the particle diameter cannot be increased by subsequent OS annealing. For example, in order to control the temperature of the object to be deposited, the deposition can be performed while cooling the object to be deposited. For example, the object to be deposited can be cooled from the surface opposite to the depositing surface so that the temperature of the depositing surface of the object to be deposited (hereinafter, referred to as “deposition temperature”) is lower than or equal to 100° C., lower than or equal to 70° C., lower than or equal to 50° C., or lower than or equal to 30° C. In particular, the deposition temperature of the oxide semiconductor film 22 is preferably lower than or equal to 50° C. When the oxide semiconductor film 22 is formed while the substrate 11 is cooled, the oxide semiconductor film 22 with few crystalline components can be obtained immediately after the deposition.

In the sputtering process, the oxide semiconductor film 22 having an amorphous structure is deposited under the condition of an oxygen partial pressure of less than or equal to 10%. When the oxygen partial pressure is high, the oxide semiconductor film 22 immediately after the deposition contains microcrystals due to excessive oxygen contained in the oxide semiconductor film 22. Therefore, the oxide semiconductor film 22 is preferably deposited under the condition that the oxygen partial pressure is low. For example, the oxygen partial pressure is greater than or equal to 1% and less than or equal to 5%, preferably greater than or equal to 2% and less than or equal to 4%. The distribution of oxygen in the deposition apparatus tends to be uneven under the condition that the oxygen partial pressure is less than 1%. As a result, the composition of oxygen in the oxide semiconductor film is also uneven, and the oxide semiconductor film containing a large amount of microcrystals is formed, or the oxide semiconductor film that does not crystallize even if the OS annealing treatment is performed later is deposited.

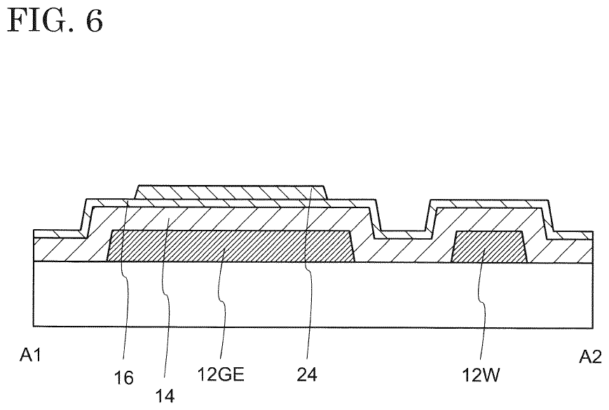

In step S1005 (“OS pattern formation”) of FIG. 3, a pattern of an oxide semiconductor layer 24 is formed (see FIG. 6). The pattern of the oxide semiconductor layer 24 is formed using photolithography. For example, a resist mask (not shown in the figures) is formed on the oxide semiconductor film 22, and the oxide semiconductor film 22 is etched using the resist mask. Wet etching may be used, or dry etching may be used as the etching method of the oxide semiconductor film 22. In the case of wet etching, etching can be performed using an acidic etching solution. For example, oxalic acid, PAN, sulfuric acid, hydrogen peroxide solution, or hydrofluoric acid can be used as the etching solution. As a result, the oxide semiconductor layer 24 having a predetermined pattern can be formed. Thereafter, the resist mask is removed.

Forming the oxide semiconductor layer 24 having a predetermined pattern (that is, patterning of the oxide semiconductor film 22) is preferably performed before OS annealing. Poly-OS after OS annealing has high etching resistance and is difficult to be patterned by etching. In addition, damage (for example, oxygen defects in the oxide semiconductor layer 24) caused when forming the oxide semiconductor layer 24 can be repaired by OS annealing by performing OS annealing after the formation of the oxide semiconductor layer 24.

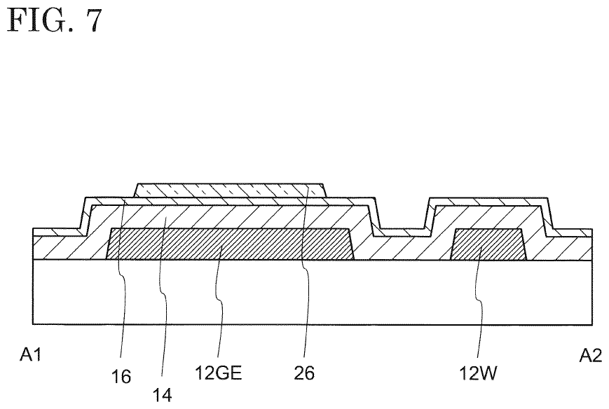

In step S1006 (“OS annealing”) of FIG. 3, the oxide semiconductor layer 26 is formed by performing a heat treatment (OS annealing) on the oxide semiconductor layer 24 after the oxide semiconductor layer 24 is formed (see FIG. 7). In OS annealing, the oxide semiconductor layer 24 is held at a predetermined reached temperature for a predetermined period. The predetermined reached temperature is higher than or equal to 300° C. and lower than or equal to 500° C., preferably higher than or equal to 350° C. and lower than or equal to 450° C. Further, the holding time at the reached temperature is greater than or equal to 15 minutes and less than or equal to 120 minutes, preferably greater than or equal to 30 minutes and less than or equal to 60 minutes. The oxide semiconductor layer 24 having an amorphous structure is crystallized by performing OS annealing, and the oxide semiconductor layer 26 having the polycrystalline structure is formed. That is, the oxide semiconductor layer 26 containing Poly-OS is formed by OS annealing.

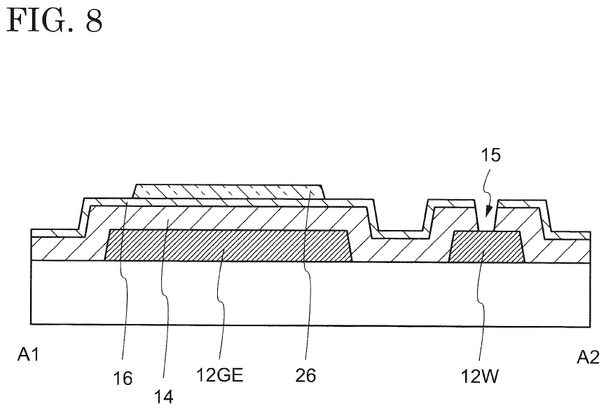

In step S1008 of FIG. 3 (“Contact hole formation”), the contact hole 15 is formed in the gate insulating layers 14 and 16 (see FIG. 8). This exposes an upper surface of the wiring 12W. In addition, in the case where the wiring 32W and the wiring 12W do not need to be connected, the step S1008 may not be performed.

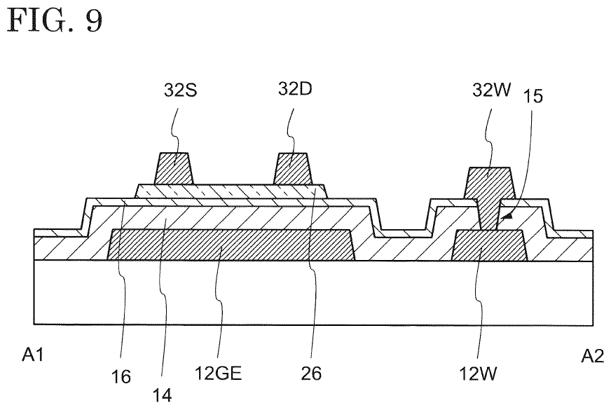

In step S1009 (“SD formation”) of FIG. 3, the source electrode 32S, the drain electrode 32D, and the wiring 32W are formed (see FIG. 9). The source electrode 32S, the drain electrode 32D, and the wiring 32W are formed by etching the conductive film deposited by a sputtering method. The same conductive material for the gate electrode 12GE is used for the source electrode 32S and the drain electrode 32D. A conductive material may be used in a single layer or in a stacked layer as the source electrode 32S, the drain electrode 32D, and the wiring 32W. A stacked structure of MoW alloy, Al, and MoW alloy (MoW/Al/MoW structure), a single layer structure of MoW alloy (MoW structure), a single layer structure of Ti (Ti structure), and a stacked structure of Ti, Al, and Ti (Ti/Al/Ti structure) are exemplified in the present embodiment.

Patterning using wet etching or dry etching is performed in order to form the source electrode 32S, the drain electrode 32D, and the wiring 32W. An etching solution is used in the wet etching. For example, a solution containing at least two selected from a group consisting of phosphoric acid, acetic acid, nitric acid, hydrofluoric acid, hydrochloric acid, sulfuric acid, and oxalic acid can be used as the etching solution. Specifically, a mixed acid etching solution containing phosphoric acid, acetic acid, and nitric acid as main components can be used as the etching solution. In addition, a mixed solution of hydrogen peroxide solution and ammonia solution (hereinafter, referred to as “H₂O₂/NH₃ solution”) can also be used as the etching solution. An etching gas is used in the dry etching. For example, a fluorine-containing gas such as a sulfur hexafluoride gas (SF₆) (hereinafter, referred to as “fluorine-based gas”) or a chlorine-containing gas such as a chlorine gas (Cl₂) (hereinafter, referred to as “chlorine-based gas”) is used as the etching gas.

Poly-OS has excellent etching resistance. Specifically, the etching rate for the etching solution or the etching gas used in forming the source electrode 32S and the drain electrode 32D is very small. This means that Poly-OS is hardly etched by the etching solution or etching gas. Therefore, even if a conductive film is directly deposited on the oxide semiconductor layer 26 and the source electrode 32S and the drain electrode 32D are formed by patterning the conductive film in the semiconductor device 10, the channel region of the oxide semiconductor layer 26 is hardly etched.

For example, the etching rate of the oxide semiconductor layer 26 with respect to the etching solution used in forming the source electrode 32S and the drain electrode 32D is less than or equal to 0.1 nm/sec, or less than or equal to 0.01 nm/sec. In addition, the etching rate of the oxide semiconductor layer 26 with respect to the etching gas used in forming the source electrode 32S and the drain electrode 32D is less than or equal to 0.5 nm/sec, or less than or equal to 0.1 nm/sec. For example, the etching rate of the oxide semiconductor layer 26 with respect to a chlorine-based gas is less than or equal to 0.1 nm/sec.

In the case where the source electrode and the drain electrode are formed on the oxide semiconductor, the oxide semiconductor layer is also etched by etching the source electrode and the drain electrode in the semiconductor device using the oxide semiconductor having no polycrystalline structure such as IGZO. Specifically, the etching rate of IGZO with respect to the chlorine-containing gas is 1.0 nm/sec, and in view of the fact that the channel region is etched at this etching rate, the oxide semiconductor film needs to be deposited thickly in advance. For example, in the case of manufacturing a semiconductor device in which the thickness of the channel region is less than or equal to 40 nm, an oxide semiconductor film with a thickness of about 65 nm is formed and the etching time needs to be adjusted so that the thickness of the channel region is less than or equal to 40 nm when forming the source electrode and the drain electrode. However, when the etching rate is high, it is difficult to precisely control the thickness of the channel region by the etching time. In this case, the variation in the thickness of the channel region increases.

In addition, a concave portion is formed on the upper surface of the oxide semiconductor layer when the thickness of the channel region is greatly reduced. Although the interlayer insulating layer provided over the oxide semiconductor layer is deposited so as to cover the concave portion, the interlayer insulating layer cannot sufficiently cover the concave portion when a depth of the concave portion is large. That is, a gap may be formed between the oxide semiconductor layer and the interlayer insulating layer or between the source electrode and drain electrode and the interlayer insulating layer. This can be a factor that causes variations in not only the electrical characteristics but also the reliability of the semiconductor device.

In contrast, the oxide semiconductor layer 26 having the polycrystalline structure can have 0.00 nm/sec to 0.1 nm/sec etching rates, preferably 0.00 nm/sec to 0.06 nm/sec, in both dry etching and wet etching. That is, the oxide semiconductor layer 26 having the polycrystalline structure has a lower etching rate and higher etching resistance than the oxide semiconductor layer using IGZO. Thus, the thickness of the channel region can be controlled without considering a decrease in the thickness of the oxide semiconductor layer. Therefore, the oxide semiconductor film can be formed with a thickness greater than or equal to 10 nm and less than or equal to 30 nm. Further, the selectivity of the conductive material that can be used as the source electrode 32S, the drain electrode 32D, and the wiring 32W is improved. For example, even when the conductive film with a MoW/Al/MoW structure or a MoW structure is processed by wet-etching in order to form the source electrode 32S and the drain electrode 32D, it is possible to suppress the reduction in the thickness of the oxide semiconductor layer 26.

The etching rate of the oxide semiconductor layer 26 with respect to the etching solution used when forming the source electrode 32S and the drain electrode 32D is very small as described above. Therefore, the thickness of the first region (that is, the source region or drain region) of the oxide semiconductor layer 26 overlapping one of the source electrode 32S and the drain electrode 32D is substantially the same as the thickness of the second region (that is, the channel region) of the oxide semiconductor layer 26 not overlapping the source electrode 32S and the drain electrode 32D. In other words, the difference between the thickness of the first region and the thickness of the second region can be controlled to be less than or equal to 5 nm, preferably less than or equal to 3 nm, and more preferably less than or equal to 1 nm. That is, variations in the thickness of the channel region are suppressed.

The interlayer insulating layer 34 is deposited on the oxide semiconductor layer 26, the source electrode 32S, and the drain electrode 32D, in step S1010 (“SiOₓ deposition”) of FIG. 3. An insulating material containing oxygen is preferably used as the interlayer insulating layer 34. For example, silicon oxide (SiOₓ) or silicon oxynitride (SiOₓN_{y}) is used as the interlayer insulating layer 34. Further, an insulating film with few defects is preferably used as the interlayer insulating layer 34. For example, in the case where the composition ratio of oxygen in the interlayer insulating layer 34 is compared with the composition ratio of oxygen in an insulating film (hereinafter, referred to as “the other insulating film”) having the same composition as the interlayer insulating layer 34, the composition ratio of oxygen in the interlayer insulating layer 34 is closer to the stoichiometric ratio with respect to the insulating film than the composition ratio of oxygen in the other insulating film. For example, when silicon oxide (SiOₓ) is used for each of the interlayer insulating layer 34 and the gate insulating layer 16, the interlayer insulating layer 34 has a composition ratio closer to the stoichiometric ratio of silicon oxide (SiO₂) than the gate insulating layer 16. A layer in which no defects are observed when evaluated by an electron-spin resonance method (ESR) may be used as the interlayer insulating layer 34.

The interlayer insulating layer 34 can be deposited using the same deposition method as the gate insulating layers 14 and 16. In order to increase the composition ratio of oxygen in the interlayer insulating layer 34, the film may be formed at a relatively low temperature (for example, a deposition temperature of less than 350° C.). Further, the interlayer insulating layer 34 may be deposited at a deposition temperature of higher than or equal to 350° C. in order to form an insulating film with few defects as the interlayer insulating layer 34. Furthermore, an oxygen-implantation treatment may be performed on part of the interlayer insulating layer 34 after the interlayer insulating layer 34 is deposited.

A thickness of the interlayer insulating layer 34 is greater than or equal to 50 nm and less than or equal to 300 nm, greater than or equal to 60 nm and less than or equal to 200 nm, or greater than or equal to 70 nm and less than or equal to 150 nm.

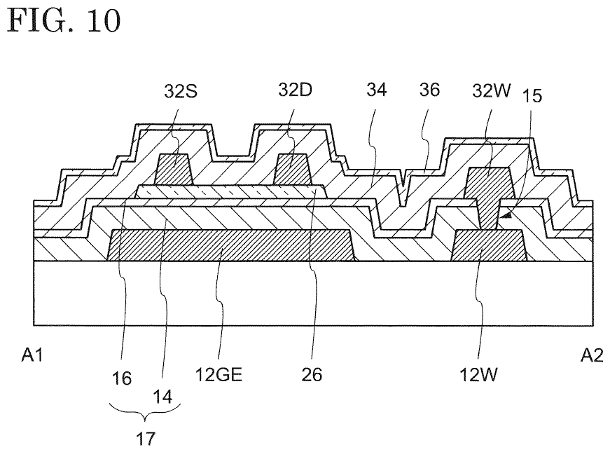

In step S1011 (“MO deposition”) of FIG. 3, a metal oxide film 36 is deposited on the interlayer insulating layer 34 (see FIG. 10). The metal oxide film 36 is deposited by a sputtering method or an atomic layer deposition method (ALD).

A metal oxide film containing aluminum as a main component is used as the metal oxide film 36. For example, an inorganic insulating film such as aluminum oxide (AlOₓ), aluminum oxynitride (AlOₓN_{y}), aluminum nitride oxide (AlNₓO_{y}), or aluminum nitride (AlNₓ) is used as the metal oxide film 36. The metal oxide film containing aluminum as a main component means that the ratio of aluminum contained in the metal oxide film is greater than or equal to 1% of the total amount of the metal oxide film. The ratio of aluminum contained in the metal oxide film 36 may be greater than or equal to 5% and less than or equal to 70%, greater than or equal to 10% and less than or equal to 60%, or greater than or equal to 30% and less than or equal to 50% of the total amount of the metal oxide film 36. The ratio may be a mass ratio or a weight ratio.

A thickness of the metal oxide film 36 is greater than or equal to 1 nm and less than or equal to 50 nm, preferably greater than or equal to 1 nm and less than or equal to 30 nm. Aluminum oxide is preferably used as the metal oxide film 36. Aluminum oxide has a high barrier property against gas such as oxygen or hydrogen. In this case, the barrier property refers to a function of suppressing a gas such as oxygen or hydrogen from passing through the aluminum oxide. That is, it means that the gas such as oxygen or hydrogen in the layer provided below the aluminum oxide film is not moved to the layer provided over the aluminum oxide film. Alternatively, it means that the gas such as oxygen or hydrogen in the layer provided over the aluminum oxide film is not moved to the layer arranged below the aluminum oxide film.

In addition, a metal oxide containing a metal other than aluminum as a main component may be used as the metal oxide film 36. For example, indium tin oxide (ITO), indium zinc oxide (IZO), indium gallium zinc oxide (IGZO), or the like can be used as the metal oxide film 36.

In step S1012 (“Oxidation annealing”) of FIG. 3, a heat treatment is performed while the interlayer insulating layer 34 and the metal oxide film 36 are deposited over the oxide semiconductor layer 26 (see FIG. 10). In this case, for example, the oxidation annealing may be performed at higher than or equal to 300° C. and lower than or equal to 450° C. As a result, the oxygen emitted from the interlayer insulating layer 34 is supplied to the oxide semiconductor layer 26. Arranging the metal oxide film 36 so as to cover the substrate 11 makes it possible to suppress the oxygen released from the interlayer insulating layer 34 from being released to the outside of the metal oxide film 36.

Many oxygen defects occur in the oxide semiconductor layer 26 during the process from the deposition of the oxide semiconductor layer 26 to the deposition of the interlayer insulating layer 34 on the oxide semiconductor layer 26. However, the oxygen released from the interlayer insulating layer 34 is supplied to the oxide semiconductor layer 26 by the oxidation annealing of step S1012, and the oxygen defects are repaired.

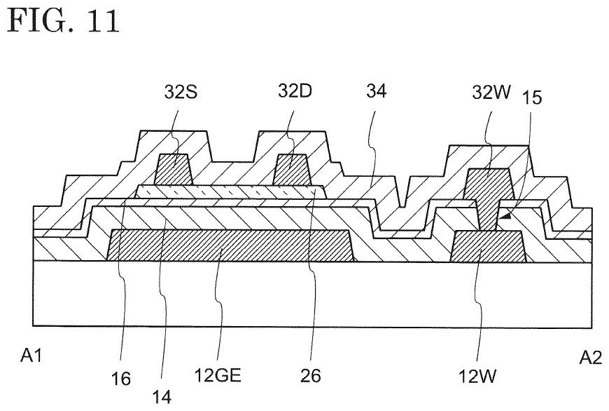

In step S1013 (“MO removal”) of FIG. 3, the metal oxide film 36 is removed (see FIG. 11). For example, the metal oxide film 36 may be removed using dilute hydrofluoric acid (DHF).

In step S1014 (“SiNₓ deposition”) of FIG. 3, the interlayer insulating layer 38 is deposited on the interlayer insulating layer 34. An insulating material containing nitrogen is preferably used for the interlayer insulating layer 38. For example, silicon nitride (SiNₓ) or silicon nitride oxide (SiNₓO_{y}) is used for the interlayer insulating layer 38. The interlayer insulating layer 38 can be deposited using the same deposition method as the gate insulating layers 14 and 16.

The semiconductor device 10 shown in FIG. 1 can be manufactured through the above steps.

In the semiconductor device 10 manufactured by the above manufacturing method, variations in the shape of the oxide semiconductor layer 26 are suppressed. In particular, variations in the thickness of the channel region can be reduced. As a result, the semiconductor device 10 has stable electrical characteristics.

Therefore, the manufacturing variations of the semiconductor device 10 are reduced and the yield is improved.

### Second Embodiment

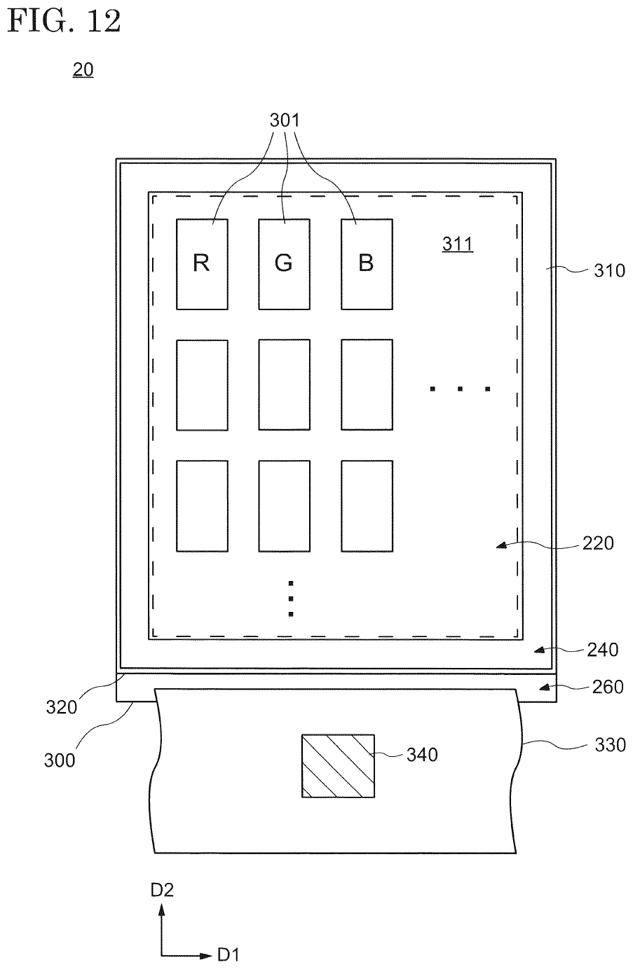

A display device 20 using the semiconductor device 10 according to an embodiment of the present invention is described with reference to FIGS. 12 to 15. A configuration in which the semiconductor device 10 described in the First Embodiment is applied to a circuit of a liquid crystal display device is described in the embodiment described below.

### [Outline of Display Device 20]

FIG. 12 is a schematic plan view showing an outline of the display device 20 according to an embodiment of the present invention. The display device 20 includes an array substrate 300, a sealing portion 310, a counter substrate 320, and a flexible printed circuit board 330 (FPC 330), and an IC chip 340, as shown in FIG. 12. The array substrate 300 and the counter substrate 320 are bonded together by the sealing portion 310. A plurality of pixel circuits 301 is arranged in a matrix in a liquid crystal region 220 surrounded by the sealing portion 310. The liquid crystal region 220 is a region that overlaps a liquid crystal element 311 described later in a plan view.

A sealing region 240 where the sealing portion 310 is provided is a region around the liquid crystal region 220. The FPC 330 is provided in a terminal region 260. The terminal region 260 is a region where the array substrate 300 is exposed from the counter substrate 320 and is provided outside the sealing region 240. The outside of the sealing region 240 means the region surrounded by the region where the sealing portion 310 is provided and the outside of the sealing portion 310. The IC chip 340 is provided on the FPC 330. The IC chip 340 supplies a signal for driving each pixel circuit 301.

### [Circuit Configuration of Display Device 20]

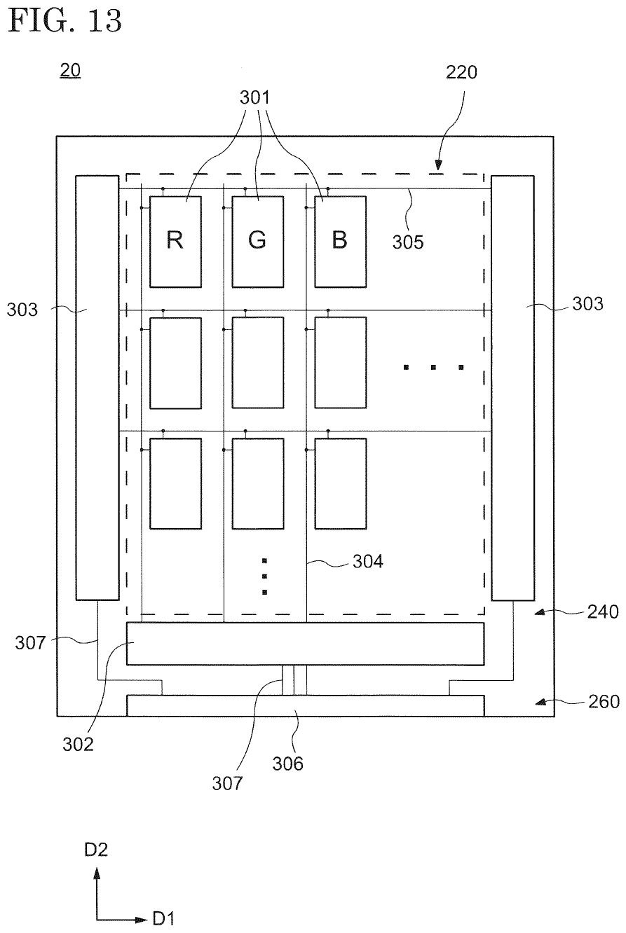

FIG. 13 is a block diagram showing a circuit configuration of the display device 20 according to an embodiment of the present invention. A source driver circuit 302 is provided at a position adjacent to the liquid crystal region 220 in which the pixel circuit 301 is arranged in the second direction D2 (column direction), and a gate driver circuit 303 is provided at a position adjacent to the liquid crystal region 220 in the first direction D1 (row direction), as shown in FIG. 13. The source driver circuit 302 and the gate driver circuit 303 are provided in the sealing region 240. However, the region where the source driver circuit 302 and the gate driver circuit 303 are provided is not limited to the sealing region 240, and any region may be used as long as it is outside the region where the pixel circuit 301 is provided.

A source wiring 304 extends from the source driver circuit 302 in the second direction D2 and is connected to the plurality of pixel circuits 301 arranged in the second direction D2. The gate electrode 12GE extends from the gate driver circuit 303 in the first direction D1 and is connected to the plurality of pixel circuits 301 arranged in the first direction D1.

A terminal portion 306 is provided in the terminal region 260. The terminal portion 306 and the source driver circuit 302 are connected by a connecting wiring 307. Similarly, the terminal portion 306 and the gate driver circuit 303 are connected by the connecting wiring 307. The FPC 330 is connected to the terminal portion 306, an external device to which the FPC 330 is connected is connected to the display device 20, and each pixel circuit 301 provided in the display device 20 is driven by a signal from the external device.

The semiconductor device 10 according to the first embodiment is used as a transistor included in the pixel circuit 301, the source driver circuit 302, and the gate driver circuit 303.

### [Pixel Circuit 301 of Display Device 20]

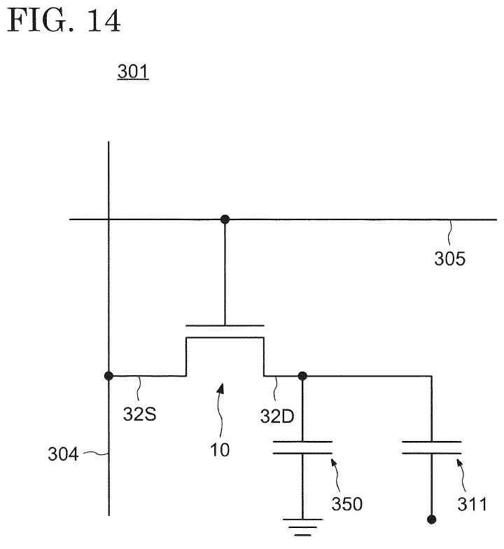

FIG. 14 is a circuit diagram showing the pixel circuit 301 of the display device 20 according to an embodiment of the present invention. The pixel circuit 301 includes elements such as the semiconductor device 10, a storage capacitor 350, and the liquid crystal element 311, as shown in FIG. 14. The semiconductor device 10 includes the gate electrode 12GE, the oxide semiconductor layer 26, the source electrode 32S, and the drain electrode 32D. The gate electrode 12GE is connected to a gate wiring 305. The source electrode 32S is connected to the source wiring 304. The drain electrode 32D is connected to the storage capacitor 350 and the liquid crystal element 311.

### [Configuration of Display Device 20]

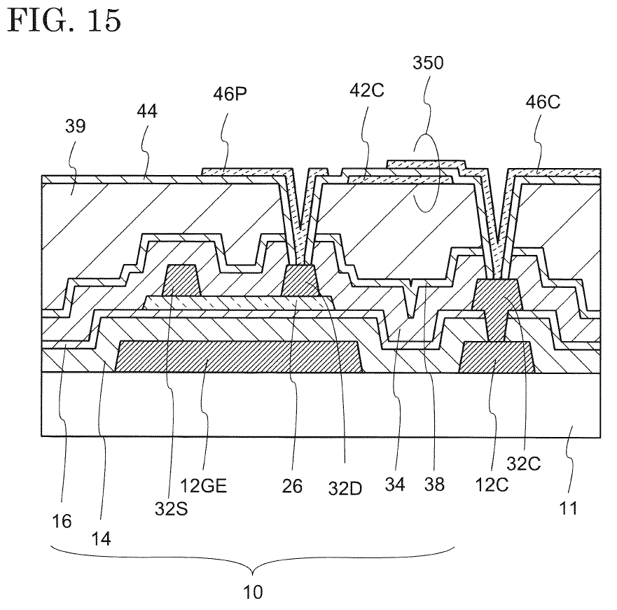

FIG. 15 is a schematic cross-sectional view of the display device 20 according to an embodiment of the present invention. The semiconductor device 10 is applied to the display device 20 shown in FIG. 15.

The gate electrode 12GE is provided on the substrate 11 as shown in FIG. 15. The gate insulating layers 14 and 16 are provided over the gate electrode layer 12GE. The oxide semiconductor layer 26 is provided over the gate insulating layers 14 and 16. The source electrode 32S and the drain electrode 32D are provided on the oxide semiconductor layer 26.

The interlayer insulating layers 34 and 38 are arranged over the source electrode 32S and the drain electrode 32D. An insulating layer 39 is provided over the interlayer insulating layers 34 and 38. The insulating layer 39 is provided in order to reduce unevenness caused by the semiconductor device 10. A contact hole is formed in the interlayer insulating layers 34 and 38 and the insulating layer 39 so as to expose the upper surface of the source electrode 32S. A common electrode 42C provided in common to a plurality of pixels is provided on the insulating layer 39. An insulating layer 44 is provided on the common electrode 42C. The insulating layer 44 is provided inside the contact hole. Forming the insulating layer 44 with a silicon nitride film makes it possible to suppress moisture from entering from the contact hole via the insulating layer 44. A pixel electrode 46P is provided on the insulating layer 44 and inside the contact hole. The pixel electrode 46P is connected to the drain electrode 32D.

Further, a wiring 12C is provided over the substrate 11 and is connected to a wiring 32C via the contact hole provided in the gate insulating layers 14 and 16. The wiring 12C and the wiring 32C function as a capacitance wiring. Furthermore, an electrode 46C is provided over the insulating layer 39 and inside the opening. The storage capacitor 350 is formed by the common electrode 42C, the insulating layer 44, and the electrode 46C.

Although a configuration in which the semiconductor device 10 is used for the pixel circuit 301 is exemplified in the present embodiment, the semiconductor device 10 may be used for a peripheral circuit including the source driver circuit 302 and the gate driver circuit 303.

### Third Embodiment

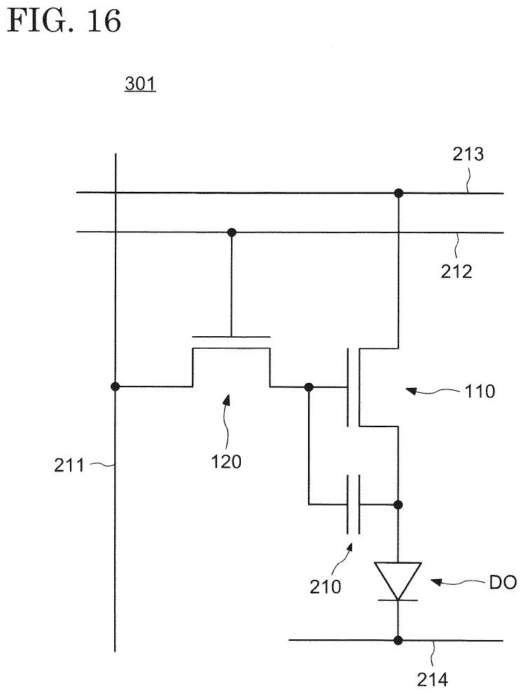

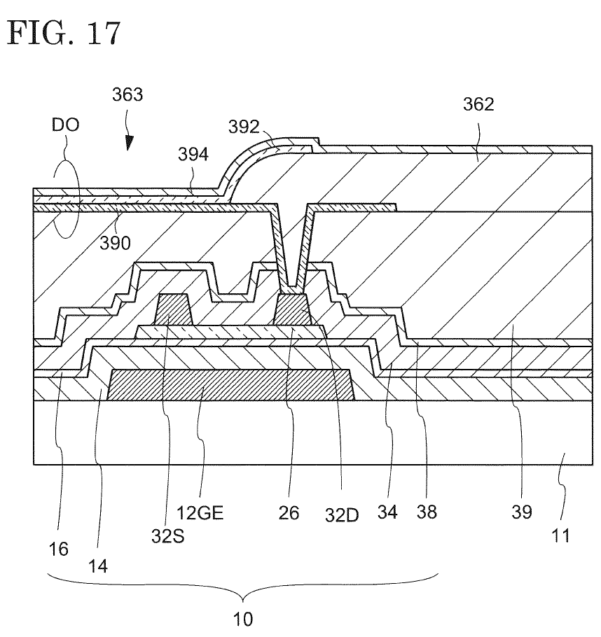

The display device 20 using the semiconductor device 10 according to an embodiment of the present invention is described with reference to FIGS. 16 and 17. A configuration in which the semiconductor device 10 described in the First Embodiment is applied to a circuit of an organic EL display device is described in the present embodiment. Since the outline and circuit configuration of the display device 20 are the same as those shown in FIGS. 12 and 13, details are omitted.

### [Pixel Circuit 301 of Display Device 20]

FIG. 16 is a circuit diagram showing a pixel circuit of the display device 20 according to an embodiment of the present invention. The pixel circuit 301 includes elements such as a driving transistor 110, a select transistor 120, a storage capacitor 210, and a light-emitting element DO, as shown in FIG. 16. The driving transistor 110 and the select transistor 120 have the same configuration as that of the semiconductor device 10. A source electrode of the select transistor 120 is connected to a signal line 211, and a gate electrode of the select transistor 120 is connected to a gate line 212. A source electrode of the driving transistor 110 is connected to an anode power line 213, and a drain electrode of the driving transistor 110 is connected to one end of the light-emitting element DO. The other end of the light-emitting element DO is connected to a cathode power line 214. A gate electrode of the driving transistor 110 is connected to a drain electrode of the select transistor 120. The storage capacitor 210 is connected to the gate electrode and drain electrode of the driving transistor 110. A gradation signal that determines an emission intensity of the light-emitting element DO is supplied to the signal line 211. A signal for selecting a pixel row to which the gradation signal is written is supplied to the gate line 212.

### [Cross-Sectional Structure of Display Device 20]

FIG. 17 is a schematic cross-sectional view showing a configuration of the display device 20 according to an embodiment of the present invention. Although the configuration of the display device 20 shown in FIG. 17 is similar to that of the display device 20 shown in FIG. 15, the structure above the insulating layer 39 of the display device 20 shown in FIG. 17 is different from the structure above the insulating layer 39 of the display device 20 shown in FIG. 15. Hereinafter, among the configuration of the display device 20 shown in FIG. 17, the same configurations as those of the display device 20 shown in FIG. 15 are omitted, and differences between the two are described.

The display device 20 includes a pixel electrode 390, a light-emitting layer 392, and a common electrode 394 (the light emitting element DO) above the insulating layer 39, as shown in FIG. 17. The pixel electrode 390 is provided on the insulating layer 39 and inside the contact hole formed in the interlayer insulating layers 34 and 38 and the insulating layer 39. An insulating layer 362 is provided on the pixel electrode 390. An opening 363 is provided in the insulating layer 362. The opening 363 corresponds to the light emitting region. That is, the insulating layer 362 defines a pixel. The light emitting layer 392 and the common electrode 394 are provided over the pixel electrode 390 exposed by the opening 363. The pixel electrode 390 and the light emitting layer 392 are provided separately for each pixel. On the other hand, the common electrode 394 is arranged in common to a plurality of pixels. Different materials are used for the light emitting layer 392 depending on the display color of the pixel.

Although the configuration in which the semiconductor device 10 described in the First Embodiment is applied to the liquid crystal display device and the organic EL display device has been exemplified in the Second Embodiment and Third Embodiment, the semiconductor device 10 may be applied to a display device (for example, a self-luminous display device or an electronic paper type display device other than the organic EL display device) other than these display devices. In addition, the semiconductor device 10 can be applied from a medium-sized display device to a large-sized display device without any particular limitation. Even when manufacturing using the large-area substrate, variations in the shape of the oxide semiconductor layer 26 in the semiconductor device 10 are small. Therefore, in the case where the semiconductor device 10 is applied to the display device 20, uneven display can be reduced. In addition, the yield in manufacturing the display device 20 can be improved.

### EXAMPLES

### Example 1

A result of the etching resistance of the oxide semiconductor layer having the polycrystalline structure is described in this example.

Samples used in this example are described. The oxide semiconductor layer (Poly-OS) having 30 nm of the polycrystalline structure was formed on a silicon wafer. Next, a conductive film was formed on the oxide semiconductor layer. A MoW structure, a MoW/Al/MoW structure, a Ti structure, and a Ti/Al/Ti structure were used as four types of conductive films.

For the conductive film with the MoW structure and the oxide semiconductor layer, one sample was wet-etched with the mixed acid etching solution, another sample was wet-etched with the H₂O₂/NH₃ solution, and another sample was dry-etched with the fluorine-based gas.

For the conductive film with the MoW/Al/MoW structure and the oxide semiconductor layer, a sample was wet-etched with the mixed acid etching solution.

For the conductive film with the Ti structure and oxide semiconductor layer, one sample was wet-etched with the H₂O₂/NH₃ solution, another sample was dry-etched with the fluorine-based gas, and another sample was dry-etched with the chlorine-based gas.

For the conductive film with the Ti/Al/Ti structure and the oxide semiconductor layer, one sample was wet-etched with the H₂O₂/NH₃ solution for Ti, wet-etched with the mixed acid etching solution for Al, and wet-etched with the H₂O₂/NH₃ solution for Ti, and the other sample was dry-etched with the chlorine-based gas.

In addition, the “mixed acid AT-2F (product name)” manufactured by Rasa Industries, Ltd. was used as the mixed acid etching solution. The proportion of phosphoric acid in the mixed acid etching solution is about 65%. Further, the temperature of the mixed acid etching solution was set to 40° C. (with temperature adjustment) and the temperature of the H₂O₂/NH₃ solution was set to 22° C. (without temperature adjustment, room temperature) when the samples were etched.

Next, a sample used in a comparative example is described. 40 nm of an IGZO oxide semiconductor layer was deposited on a silicon wafer. Then, a conductive film was formed on the oxide semiconductor layer. The Ti structure was used as the conductive film. For the conductive film with the Ti structure and the oxide semiconductor layer, the sample was dry-etched with the chlorine-based gas.

The etching rates (unit: [nm/sec]) of the polycrystalline oxide semiconductor layer relative to estimated over-etching times after processing the various conductive film are shown in Table 1 as the examples.

TABLE 1

| | Wet etching | | Dry etching | |
|---|---|---|---|---|
| | Mixed acid | H₂O₂/NH₃ | Fluorine- | Chlorine- |
| | etching solution | solution | based gas | based gas |
| MoW structure | 0.00 | 0.02 | 0.00 | — |
| MoW/Al/MoW | 0.00 | — | — | — |
| structure | | | | |
| Ti structure | — | 0.06 | 0.05 | 0.22 |

| | | | |
|---|---|---|---|
| Ti/Al/Ti | 0.02 | — | 0.30 |
| structure | | | |

The etching rate of the oxide semiconductor layer (IGZO) relative to the estimated over-etching time after processing the conductive film with the Ti structure was 1.00 nm/sec, as a comparative example.

It was shown that the oxide semiconductor layer having the polycrystalline structure has higher etching resistance than the amorphous oxide semiconductor layer (IGZO), as shown in Table 1. Further, it was shown that the etching rate was 0.00 nm/sec to 0.06 nm/sec in the case of etching with the mixed acid etching solution, etching with the H₂O₂/NH₃ solution, and etching with the fluorine-based gas. It was shown that even when etching is performed using the chlorine-based gas, it has a sufficiently high etching resistance than the oxide semiconductor layer (IGZO).

### Example 2

Next, a result of measuring the electrical characteristics of the semiconductor device 10 manufactured according to the flowchart shown in FIG. 3 of the First Embodiment is described.

Samples A to C prepared as the semiconductor device 10 are described in Example 2. In the manufacture of the samples A to C, step S1008 in the flowchart showing the method for manufacturing the semiconductor device 10 shown in FIG. 3 was omitted.

The gate electrode 12GE was formed on the substrate and the gate insulating layers 14 and 16 were formed over the gate electrode 12GE. 30 nm of the oxide semiconductor film 22 was formed over the gate insulating layers 14 and 16. The oxide semiconductor layer 24 was formed by processing the oxide semiconductor film 22, and the polycrystalline oxide semiconductor layer 26 (Poly-OS) was formed by performing OS annealing at a controlled temperature in the range of 350° C. to 450° C.

The MoW/Al/MoW structure was formed as the conductive film on the oxide semiconductor layer 26, and the source electrode and the drain electrode were formed by performing wet etching on the conductive film using the mixed acid etching solution. Then, 10 nm of the aluminum oxide layer was formed as the metal oxide film 36 after the interlayer insulating layer 34 was formed, and the metal oxide film 36 was removed after performing oxidation annealing. Finally, the interlayer insulating layer 38 was formed on the interlayer insulating layer 34.

Samples A to C have different conditions for the deposition temperature of the interlayer insulating layer 34. The deposition temperatures of the interlayer insulating layer 34 in Samples A to C are 300° C., 325° C., and 350° C., respectively.

When the thickness of the oxide semiconductor layer 26 in each of Samples A to C was measured, the difference between the thickness of the channel region and the thickness of the source or drain region was less than 2 nm.

Next, the electrical characteristics of Samples A to C were measured. The measurement conditions for the electrical characteristics are shown in Table 2.

TABLE 2

| | |
|---|---|
| Channel region size | W/L = 6.0 μm/6.0 μm |
| Source-drain voltage | 0.1 V, 10 V |
| Gate voltage | −40 V to +40 V (0.2 V Step) |
| Measurement environment | room temperature, dark room |

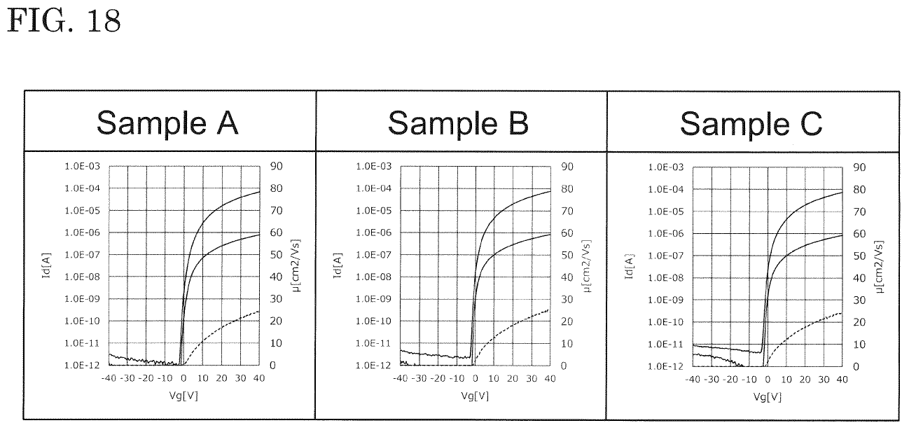

FIG. 18 is a diagram showing the electric characteristics (Id-Vg characteristics) of Samples A to C. The horizontal axis represents the gate voltage Vg, and the vertical axis represents the drain current (Id). Further, the field-effect mobility (field-effect mobility in the linear region) and the threshold value calculated from the electrical characteristics shown in FIG. 18 are shown in Table 3.

TABLE 3

| | Field-effect mobility | Threshold value |
|---|---|---|
| | (cm²/Vs) | (V) |
| Sample A | 24.24 | 1.07 |
| Sample B | 25.23 | −0.06 |
| Sample C | 24.34 | −0.35 |

As can be understood from FIG. 18 and Table 3, in Samples A to C, even when the interlayer insulating layer 34 having a different deposition temperature is in contact with the oxide semiconductor layer (Poly-OS) having a polycrystalline structure, the stable field-effect mobility is obtained. That is, the semiconductor device 10 can obtain stable electrical characteristics because the shape of the oxide semiconductor layer 26 (in particular, the thickness of the channel region) is controlled.

In addition, when the deposition temperature of the interlayer insulating layer 34 increases, the threshold value of the electrical characteristics shifts to the negative side. Therefore, when the threshold value is made an enhancement type in the electrical characteristics of the semiconductor device 10, it is preferable to deposit the interlayer insulating layer 34 at lower than or equal to 300° C.

Each of the embodiments and modifications described above as the embodiments of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a gate electrode;
a gate insulating layer over the gate electrode;
an oxide semiconductor layer having a polycrystalline structure over the gate insulating layer;
a source electrode and a drain electrode over the oxide semiconductor layer; and
an interlayer insulating layer in contact with the oxide semiconductor layer, the interlayer insulating layer covering the source electrode and the drain electrode,
wherein the oxide semiconductor layer comprises a first region overlapping one of the source electrode and the drain electrode and a second region in contact with the interlayer insulating layer, and
a difference between a film thickness of the first region and a film thickness of the second region is less than or equal to 5 nm.

2. The semiconductor device according to claim 1, wherein an etching rate of the oxide semiconductor layer with respect to an etching solution used in forming the source electrode and the drain electrode is less than or equal to 0.1 nm/sec.

3. The semiconductor device according to claim 2, wherein the etching solution is a solution containing at least two selected from the group consisting of phosphoric acid, acetic acid, nitric acid, hydrofluoric acid, hydrochloric acid, sulfuric acid, and oxalic acid.

4. The semiconductor device according to claim 1, wherein an etching rate of the oxide semiconductor layer with respect to an etching gas used in forming the source electrode and the drain electrode is less than or equal to 0.5 nm/sec.

5. The semiconductor device according to claim 4,
wherein the etching gas is a gas containing fluorine, and
the etching rate is less than or equal to 0.1 nm/sec.

6. The semiconductor device according to claim 1, wherein the film thickness of the first region is greater than or equal to 10 nm and less than or equal to 30 nm.

7. The semiconductor device according to claim 1,
wherein the oxide semiconductor layer comprises indium and at least one or more metal elements, and
a ratio of the indium to the indium and the at least one or more metal elements is greater than or equal to 50%.

8. A method for manufacturing a semiconductor device comprising the steps of:
forming a gate electrode;
forming a gate insulating layer over the gate electrode;
forming an oxide semiconductor layer having a polycrystalline structure over the gate insulating layer;
depositing a conductive film over the oxide semiconductor layer;
patterning the conductive film by etching to form a source electrode and a drain electrode; and
forming an interlayer insulating layer in contact with the oxide semiconductor layer, the interlayer insulating layer covering the source electrode and the drain electrode,
wherein the oxide semiconductor layer comprises a first region overlapping one of the source electrode and the drain electrode and a second region in contact with the interlayer insulating layer, and
a difference between a film thickness of the first region and a film thickness of the second region is less than or equal to 5 nm.

9. The method for manufacturing a semiconductor device according to claim 8,
wherein an etching solution is used in the etching, and
an etching rate of the oxide semiconductor layer with respect to the etching solution is less than or equal to 5 nm.

10. The method for manufacturing a semiconductor device according to claim 9, wherein the etching solution is a solution containing at least two selected from the group consisting of phosphoric acid, acetic acid, nitric acid, hydrofluoric acid, hydrochloric acid, sulfuric acid, and oxalic acid.

11. The method for manufacturing a semiconductor device according to claim 8,
wherein an etching gas is used in the etching, and
an etching rate of the oxide semiconductor layer with respect to the etching gas is less than or equal to 0.5 nm/sec.

12. The method for manufacturing a semiconductor device according to claim 11,
wherein the etching gas is a gas containing fluorine, and
the etching rate is less than or equal to 0.1 nm/sec.

13. The method for manufacturing a semiconductor device according to claim 8, wherein the film thickness of the first region is greater than or equal to 10 nm and less than or equal to 30 nm.

14. The method for manufacturing a semiconductor device according to claim 8,
wherein the oxide semiconductor layer comprises indium and at least one or more metal elements, and
a ratio of the indium to the indium and the at least one or more metal elements is greater than or equal to 50%.

15. The method for manufacturing a semiconductor device according to claim 14, wherein the oxide semiconductor layer is formed by performing a heat treatment on an oxide semiconductor film having an amorphous structure.
